(19) United States
(12) Patent Application Publication
(10) Pub. No.: US 2011/0204885 A1
(43) Pub. Date: Aug. 25, 2011

(54) DETECTION OF THE STATE OF ELECTRICAL EQUIPMENT OF A VEHICLE

(75) Inventors: Alexis Le Goff, Versailles (FR); Roland Blanpain, Entre-Deux-Guiers (FR)

(73) Assignee: Commissariat A L'Energie Atomique et Aux Energies Alternatives, Paris (FR)

(21) Appl. No.: 13/008,550

(22) Filed: Jan. 18, 2011

(30) Foreign Application Priority Data
Jan. 21, 2010 (FR) 10/50380

(51) Int. Cl. G01R 33/02

(52) U.S. Cl. 324/244

(57) ABSTRACT

A method for detecting an on or off state of electrical equipment of a vehicle, wherein the amplitudes of the magnetic field measured in at least two directions are analyzed to isolate the respective contributions of the different pieces of electrical equipment and deduce their state.

### BACKGROUND OF THE INVENTION

1. Field of the Invention

The present invention generally relates to vehicles and, more specifically, the detection of an on or off state of electrical equipment of a vehicle. The present invention more specifically applies to motor vehicles.

2. Discussion of Prior Art

In vehicles, and especially motor vehicles, it is desirable to detect whether a bulb of a headlight, of a blinker or another piece of electrical equipment is defective. In particular, if the driver can easily notice, by night, that one of the front lights is not working, he may not notice a malfunction of the rear lights or of the stop lights. This issue also arises for electrical vehicle equipment other than the lighting equipment.

Different mechanisms have already been provided to detect a disconnection of a lamp and identify the concerned lamp.

For example, U.S. Pat. No. 5,744,961 describes a device comprising a square horseshoe magnetic core, having a Hall probe placed in its airgap. The power supply leads between the battery and each of the lamps are wound around the magnetic core with a different number of turns for each lamp. The exploitation of the magnetic field measurement in the airgap enables to determine the on or off state of the lamps. Such a solution requires deviating the different power supply leads of the electrical equipment to wind them around a magnetic core.

A similar solution is described in U.S. Pat. No. 5,041,761.

It would be desirable to detect the on or off state of different pieces of electrical equipment of a vehicle without having to divert the leads towards a magnetic core.

### SUMMARY OF THE INVENTION

An object of an embodiment of the present invention is to overcome all or part of the disadvantages of known systems of electrical equipment disconnection in a vehicle.

An object of another embodiment of the present invention is to provide a solution requiring no modification of the electric connections.

An object of another embodiment of the present invention is to provide a solution adaptable to existing vehicles.

To achieve all or part of these and other objects, the present invention provides a method for detecting an on or off state of electrical equipment of a vehicle, wherein the amplitudes of the magnetic field measured in at least two directions are analyzed to isolate the respective contributions of the different pieces of electrical equipment and deduce their state.

According to an embodiment of the present invention, the analysis takes into account a training phase in which the pieces of equipment are successively and individually turned on and off.

According to an embodiment of the present invention, the respective states of the pieces of equipment are obtained from values representative of the amplitude of the magnetic field in said directions and from coefficients obtained in the training phase.

According to an embodiment of the present invention, the respective states of the pieces of equipment are obtained from values representative of amplitude variations of the magnetic field in said directions and from coefficients obtained in a training phase.

According to an embodiment of the present invention, the respective states of the pieces of equipment are obtained by calculating probabilities of state combinations.

The present invention also provides a system for detecting an on or off state of electric equipment of a vehicle, comprising:

at least two magnetic sensors in different directions; and

a circuit for interpreting the signals provided by each sensor to isolate the respective contributions of the different pieces of electrical equipment to the magnetic field.

According to an embodiment of the present invention, three sensors are integrated in a three-axis magnetometer.

The present invention also provides a motor vehicle equipped with a system for detecting an on or off sate of electrical equipment.

The foregoing and other objects, features, and advantages of the present invention will be discussed in detail in the following non-limiting description of specific embodiments in connection with the accompanying drawings.

### BRIEF DESCRIPTION OF THE DRAWINGS

FIG. 1 is a simplified view of an example of motor vehicle equipped with a system according to an embodiment of the present invention;

FIG. 2 illustrates the response of a path of a magnetic sensor of FIG. 1;

FIG. 3 shows, in the form of timing diagrams, an example of shape of three magnetic sensor paths; and

FIG. 4 is a simplified electric diagram of the equipment monitored in the vehicle of FIG. 1.

### DETAILED DESCRIPTION

The same elements have been designated with the same reference numerals in the different drawings. For clarity, only those elements which are useful to the understanding of the present invention have been shown and will be described. In particular, what exploitation is made of the signals detecting the on or off (disconnected) state of electrical equipment has not been detailed, such an exploitation being compatible with usual solutions, for example, to activates indicators warning the driver, to memorize breakdowns, etc.

The present invention will be described hereafter in relation with an example of monitoring of the turning on or off of lamps for a motor vehicle. It however more generally applies to the monitoring of any electrical equipment of a vehicle.

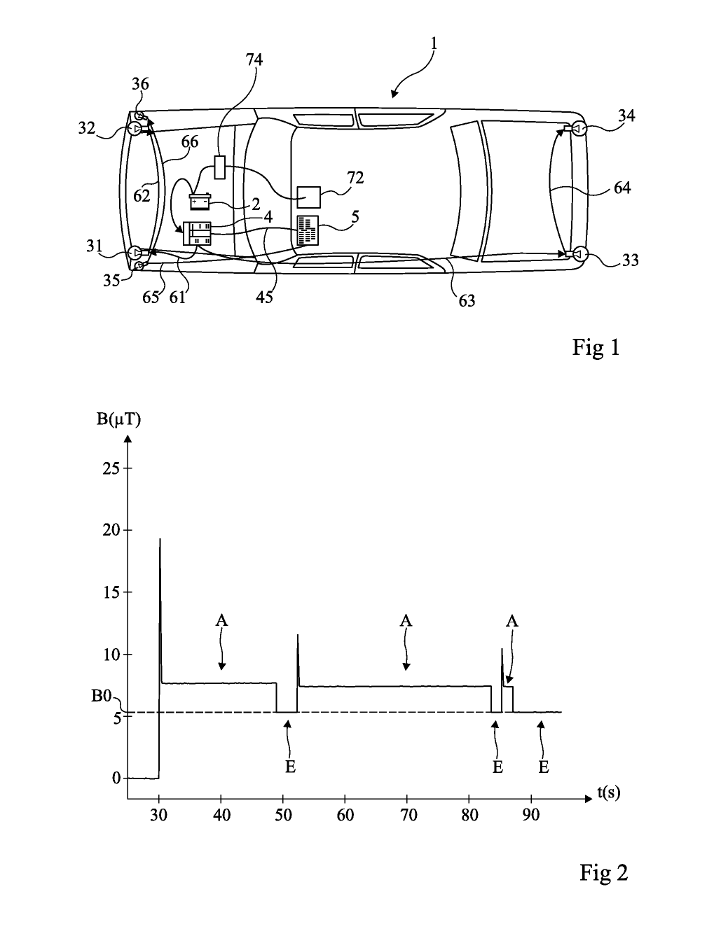

FIG. 1 is a simplified top view of a motor vehicle 1 equipped with a system for detecting an on or off state of lamps according to an embodiment of the present invention. The different vehicle lamps (and other pieces of electrical equipment) are powered by a battery 2. The example of FIG. 1 shows front lights 31 and 32, rear lights 33 and 34, and front parking lights 35 and 36. In practice, other lamps and pieces of electrical equipment may be monitored by the embodiments which will be described.

The lamps are powered via a fuse board 4 controlled by switches, generally integrated in a desk 5 of the instrument panel, and accessible by levers at the steering wheel or by dashboard controls. For simplification, elements 4 and 5 have been very schematically shown in FIG. 1, a connected by a bundle of leads 45. Lead bundles or electric connections connect fuse board 4 and/or control desk 5 to the lamps. In the representation of FIG. 1, the following connections have been illustrated:

a connection 61 of board 4 to lamp 31 and an extension 62 of this connection all the way to lamp 32 for a parallel electric connection of the front lights;

a connection 63 of board 4 to rear light 33 as well as an extension 64 all the way to light 34 for a parallel electric connection of the rear lights; and

a connection 65 of desk 5 to parking light 35 and an extension 66 all the way to parking light 36 for a parallel electric connection.

The connection of electrical equipment to a switch upstream or downstream of board 4 depends on the equipment, according to whether the switch is or not protected by a fuse. Further, other pieces of equipment are powered without using a switch other than a general vehicle power-on switch (for example, the on-board computer of the vehicle).

The system for detecting the on or off (connected or disconnected) state of the different lamps comprises at least two magnetic sensors (for example, a magnetometer 72 placed at any location in the vehicle, for example, in approximately central position). The signals representative of the magnetic field sensed by the magnetometer are provided to an interpretation and control circuit 74, powered by battery 2.

The described embodiments provide extracting, from the magnetic field measured by magnetometer 72, the respective states of the different lamps.

Indeed, when a current flows in a power supply lead of a piece of equipment, it induces a magnetic field that may be sensed by magnetometer 72.

The present invention takes advantage from the fact that each lamp is only powered by a single lead (positive voltage) and that the return to ground is performed directly through the vehicle carcass. Indeed, if the leads were paired with a connection to the negative potential of battery 2, the magnetic fields induced by opposite currents in these leads would compensate for each other.

The present invention also takes advantage from the fact that the amplitude and the orientation of the magnetic field (of its resultant at the level of each sensor) depends on the electric path between the battery and the equipment. Accordingly, it becomes possible to isolate the respective contributions of the different pieces of equipment on the measured magnetic field to detect and identify what lamp is on.

The respective contributions of the lamps to the magnetic field depend not only on the electrical paths but also on the electric intensity of the different lamps.

In the described embodiments, it is considered that the contributions of the different electric elements to the magnetic field superpose to one another. The electric current which crosses each light bulb has but two possible values, 0 or the nominal current of this bulb (for example, on the order of 1 ampere for parking lights and on the order of 5 amperes for front lights). Further, the contribution of a sum of bulbs is equal to the sum of the individual contributions of each bulb.

FIG. 2 illustrates an example of shape of the response of a magnetic sensor in successive lamp turn-on and turn-off operations. Levels A (on) and E (off), which are different according to the state of the bulb, can be observed. In this example, field B is measured in microTesla. It is considered that two parameters essentially influence the field amplitude: the amplitude of the current in the lead, and the electrical path (distance and direction) between the battery and the lamp, as seen from the sensor.

It could thus be sufficient to measure the level variations of the magnetic field measured by a sensor. Such a simplified implementation already is an improvement with respect to known systems, since it requires no modification of the wiring of the electric circuit of the vehicle. However, it is not accurate enough. Indeed, several pieces of electrical equipment are capable of generating a field having identical components on the sensor axis.

Thus, according to a preferred embodiment, the variations of the magnetic field in different directions are exploited by means of several sensors or of a multi-axis magnetometer defining several measurement paths.

By taking into account the responses on the different paths, the concerned piece of electrical equipment can be identified.

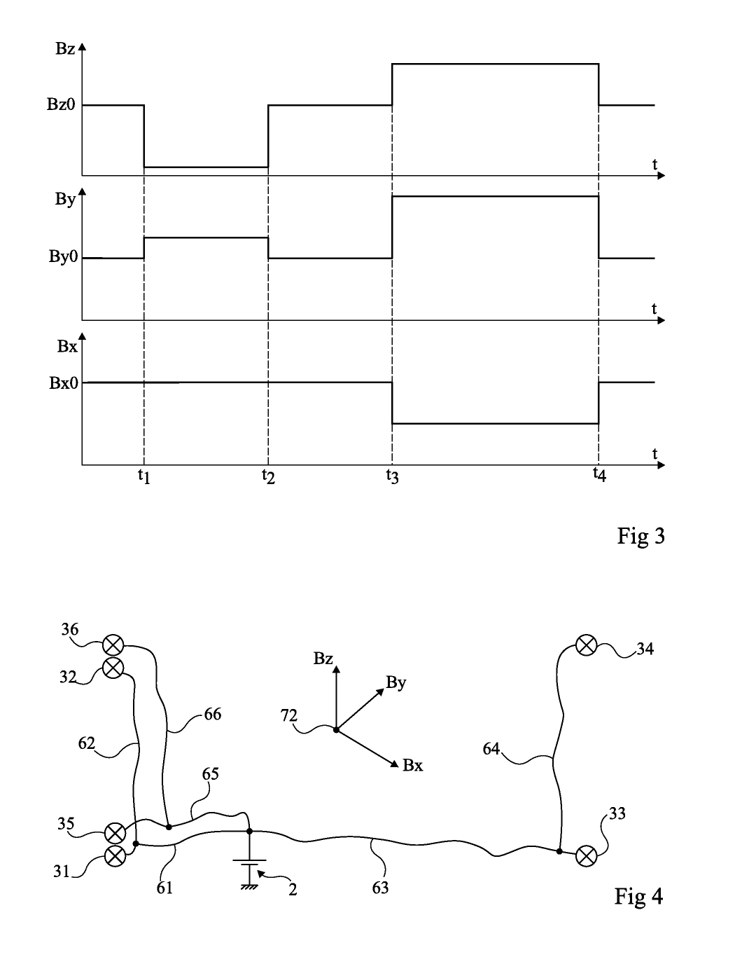

FIG. 3 illustrates, in the form of timing diagrams, an example of response of three paths Bx, By, and Bz of a three-axis magnetometer.

FIG. 4 schematically shows, from battery 2, the electric paths of the six lamps of FIG. 1.

Axes x, y, and z are in an arbitrary position with respect to the vehicle. What matters is for these axes not to be parallel to one another so that the respective contributions of the magnetic field originating from the different electric paths differ from one path to the other. Providing three orthogonal axes however maximizes the differences between the measured signals.

With respect to a reference level Bx0, By0, and Bz0 of each path, for example corresponding to the level at which the equipment to be monitored is off, the turning-on (time t1) followed by the turning-off (time t2) of first electrical equipment (for example, lamps 31 and 32) and the turning-on (time t3) and the turning-off (time t4) of other electrical equipment (for example, lamps 33 and 34) is assumed.

As appears from FIG. 3, the contribution of a same piece of equipment differs according to the path. This is due to the orientation of the magnetic field resulting from the electrical path of the equipment with respect to the sensor orientation. Further, each lamp is powered for a different path (for example, 61 for light 31 and 61+62 for light 32) even if it is controlled at the same time as another one. Accordingly, a defect of a lamp can be identified even if the other one is operative.

The different pieces of electrical equipment can thus be identified by analyzing the different responses, for example, as follows.

The sensor path is designated as i (with i ranging between 1 and m) (m being equal to 3 in the example of FIGS. 3 and 4), k (with k ranging between 1 and n, n being 6 in the example of FIGS. 1 and 4) designates a monitored electric path (a bulb), Iₖ designates the current in this path when the bulb is lit, α_{k,i} designates a geometric factor of the electric path for each path, and εₖ designates a state variable which takes value 0 or 1 according to the on or off state of the concerned bulb k (or the defectiveness of the circuit powering it). The aim is to determine the state variable εₖ of each lamp.

The magnetic field of a path i, noted Bᵢ, corresponds to the sum of products α_{k,i}*Iₖ*εₖ, plus a value Bᵢ0 representing the contribution of the outer field to this path. This translates as the following formula:

$${B}_{i} = {\sum }_{k = 1}^{n} ( {α}_{k , i} \times {I}_{k} \times {ɛ}_{k} ) + {B}_{i} 0. \qquad ( formula 1 )$$

As a first approximation, it can be considered that products α_{k,i}*Iₖ are constant for a given piece of equipment k. Further, it can be considered that the respective contributions of the non-electric ferromagnetic equipment only modify value Bᵢ0.

The previous equation can thus be written as a matrix equation:

B=M·ε+B0, (formula 2)

where B represents the measurement vector of magnetic fields Bᵢ, M represents a so-called mixing matrix of n columns and m lines comprising coefficients α_{k,i}.Iₖ, ε represents a state vector formed of 0s and 1s according to the respective states of the different monitored lamps, and B0 represents a vector of the quiescent levels of the different paths.

Mixing matrix M is determined in a training phase. For example, at the end of the vehicle manufacturing, by separately actuating the different pieces of equipment, it is possible to record the contribution of each light bulb on the different sensors (or axes) and to obtain and store the coefficients of matrix M.

In operation, the measurement of the coefficients of vector B and the knowledge of matrix M and of vector B0 enables to determine vector E, and thus the respective states of the different pieces of electrical equipment.

The detection can be improved by taking into account a variation of quiescent values B0. Indeed, the present inventor has found that, as appears from FIG. 2, magnetic field peaks appear when a lamp is switched on and that the peak is particularly significant in cold starts. Such peaks originate from current peaks which are due to the fact that bulbs have a lower resistance when cold. The present inventor considers that these peaks are sufficiently powerful to magnetize the ferromagnetic matter located close to the power supply lead and this magnetization is maintained by this environment until a greater current is applied in the lead (and thus, until the next peak). Quiescent values B0 then vary.

To take this phenomenon into account, the value jumps of the magnetic field, which indicate the turning on or off of one or several lamps, are preferably detected. Another advantage of such an embodiment is that other magnetic field variations such as terrestrial magnetic field variations or other environing magnetic disturbances are also done away with.

Using the above notations, a variation ΔB on measurement vector B corresponds to the algebraic sum of the contribution of each newly turned on or off piece of equipment. Above formula 2 becomes:

ΔB=M.Δε+B0, (formula 3)

where Δε represents a state switching vector formed of 0s and of −1s. Element Δεₖ of rank k of vector Δε is 0 if the state of lamp k has not switched during the magnetic field variation and −1 if it is one of the lamps which has contributed to this variation by turning off.

The signal processing performed by circuit 74 then amounts to detecting and evaluating the amplitude of jumps ΔB on vector B, and then estimating the state switching vector Δε based on this evaluation.

To detect the jumps on vector B and evaluate the amplitude of these jumps, a so-called Deriche algorithm, which enables to detect transitions in noisy signals, is preferably used. The magnetic noise polluting the signals provided by the magnetometer(s) is thus done away with. The Deriche algorithm is generally used in image processing to detect the contours which correspond to transitions in noisy signals. For example, article “A new operator for the detection of transitions in noisy signals” by W Y. Liu, I E Mangnin, and G. Gimenez published in Traitement du signal, volume 12 No 3, pages 225 to 236, 1995, may be used as a guideline.

The application of a Deriche operator to the different sensor signals provides pulse signals having their pulses corresponding to jumps of the measured signal. The pulse width depends on a parameter, noted α, of the operator which results from a compromise between the accuracy of the detection which requires wide pulses and the resolution (capacity of detecting close jumps) which requests short pulses.

As an example, response θᵢ(t₀) at a time to of the Deriche operator applied to a signal Bᵢ(t), may be expressed with the following formula 4:

$${θ}_{i} ( {t}_{0} ) = {\int }_{- ∞}^{+ ∞} ( - {B}_{i} ( t ) \times \frac{{( 1 - {e}^{- α} )}^{2}}{{e}^{- α}} \times ( t - {t}_{0} ) \times {e}^{- α \vert t - {t}_{0} \vert} ) d t .$$

The amplitudes of the different pulses, which are proportional to the amplitudes of the jumps in signal Bᵢ, are recorded as the measured signal. Hereafter, the amplitude of pulse θᵢ will be noted ΔBᵢ.

According to a preferred embodiment, to obtain the state switching vector, a probability for the value to correspond to reality is associated with each possible value Δεₖ of vector Δε. In practice, the results of a scanning of all possible values of vector Δε are interpreted. The method described in article “Inverse Problem Theory—Method for Data Fitting and Model Parameter Estimation”, by A. Tarantola, published by Elsevier in 1987 (pages 1 to 161) may for example be used as a guideline.

Designating as z each of the possibilities likely to be taken by vector Δε (with z ranging between 1 and 2ⁿ) and as σᵢ the standard deviation of a jump on path i, probability P_{z} for possibility z to be the combination of states corresponding to reality may be written as:

$${P}_{z} = exp ( - \frac{1}{2} \times \sqrt{{\sum }_{i} \frac{Δ {B}_{i} - {( M \times {Δɛ}_{z} )}_{i}}{{σ}_{i}}} ) . \qquad ( formula 5 )$$

By dividing, for each path i, measurement vector ΔBᵢ by standard deviation σᵢ of the concerned path (noted ΔB′ᵢ), and by calculating, for each path, a mixing matrix M′ᵢ obtained by dividing the coefficients of matrix M by standard deviation σᵢ of the concerned path, above formula 5 may be simplified to provide:

$${P}_{z} = exp ( - \frac{1}{2} \times ‖ Δ {B}_{i}^{′} - ( {M}_{i}^{′} \times {Δɛ}_{z} ) ‖ ) . \qquad ( formula 6 )$$

By calculating this probability for all vectors Δε_{z}, the combination with the highest probability provides the state switching vector.

The reliability of the detection can be further improved by taking battery voltage U into account. For example, when the vehicle motor is running, the battery voltage is higher than when the motor is stopped. Further, in the stopped state, the voltage may drop according to the current output by the battery. In this case, the intensity Iₖ crossing each piece of electrical equipment is not constant but depends on voltage U. According to another preferred embodiment, this variation is taken into account.

Magnitude Bᵢ/U is then considered, rather than Bᵢ. For example, in the training phase, the different coefficients of mixing matrix M are obtained by varying the battery voltage to take into account the resistance of the electrical equipment. Then, the measured magnetic field values (measurement vector B) are divided by the current voltage across the battery. The determination is then performed according to one of the previously-discussed embodiments based on the levels (application of formula 2) or based on the jumps (application of formula 3).

An advantage of the described embodiments is that they enable to detect a willful or incidental turning-on and turning-off in electrical equipment of a vehicle, in a particularly simple way. In particular, it is not necessary to wind each lead around a ferromagnetic core, nor is it necessary to modify the electric paths.

Another advantage is that the present invention is compatible with existing vehicles and can thus be installed as an accessory. It is sufficient to provide a training phase in which the different pieces of electrical equipment are turned on and off one after the other to parameterize the system.

It should be noted that it is not compulsory to monitor all the pieces of electrical equipment. Indeed, the switchings of a piece of electrical equipment for which the system is not parameterized will not be recognized (their contributions to the magnetic field being different from those contained in the mixing matrix).

Specific embodiments of the present invention have been described. Various alterations and modifications will occur to those skilled in the art. In particular, the selection of the electrical equipment to be monitored conditions the training phase carried out to detect their respective contribution.

Further, the practical implementation of the present invention based on the functional indications given hereabove is within the abilities of those skilled in the art. In particular, although the present invention has been described in reference to D.C. (analog) signals, calculations will in practice be performed by digital circuits requiring a sampling of the measured signals, the selection of the sampling frequency conditioning the system resolution.

Moreover, although the present invention has been described in relation with an example of lamps switched in all or nothing, the monitored electrical equipment may also be power dimming equipment, provided for the current to always remain the same at the turning-off.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. A method for detecting an on or off state of electrical equipment of a vehicle, wherein the amplitudes of the magnetic field measured in at least two directions are analyzed to isolate the respective contributions of the different pieces of electrical equipment and deduce their state.

2. The method of claim 1, wherein the analysis takes into account a training phase in which the pieces of equipment are successively and individually turned on and off.

3. The method of claim 2, wherein the respective states of the pieces of equipment are obtained from values representative of the amplitude of the magnetic field in said directions and from coefficients obtained in the training phase.

4. The method of claim 2, wherein the respective states of the pieces of equipment are obtained from values representative of amplitude variations of the magnetic field in said directions and from coefficients obtained in a training phase.

5. The method of claim 4, wherein the respective states of the pieces of equipment are obtained by calculating probabilities of state combinations.

6. A system for detecting an on or off state of electrical equipment of a vehicle, comprising:
at least two magnetic sensors in different directions; and
a circuit for interpreting the signals provided by each sensor to isolate the respective contributions of the different pieces of electrical equipment to the magnetic field.

7. The system of claim 6, comprising three sensors integrated in a three-axis magnetometer.

8. The system of claim 6, wherein the interpretation circuit implements the method of claim 1.

9. A motor vehicle equipped with the system of claim 6.
